(19) United States
(12) Patent Application Publication
(10) Pub. No.: US 2014/0174591 A1
(43) Pub. Date: Jun. 26, 2014

(54) DOPANT FUNNEL FOR LOADING AND DISPENSING DOPANT

(71) Applicant: SunEdison, Inc., St. Peters, MO (US)

(72) Inventors: John David Hilker, St. Charles, MO (US); Steven L. Kimbel, St. Charles, MO (US)

(21) Appl. No.: 14/134,830

(22) Filed: Dec. 19, 2013

Related U.S. Application Data
(60) Provisional application No. 61/740,809, filed on Dec. 21, 2012.

(51) Int. Cl. C30B 15/04; C30B 15/00

(52) U.S. Cl. CPC C30B 15/04; C30B 15/002
USPC 141/2; 117/208

(57) ABSTRACT

A dopant funnel for loading dopant pellets into a dispenser tube of a dopant dispenser is disclosed. The dopant funnel has a cup connected through a restrictor to a shaft. The cup holds random oriented dopant pellets. The restrictor meters the amount and orientation of dopant pellets being removed from the cup. The shaft is in alignment with the restrictor for delivering dopant pellets from the cup to the dispenser tube.

### CROSS REFERENCE

This application claims priority to U.S. Provisional Application No. 61/740,809 filed Dec. 21, 2012, the disclosure of which is hereby incorporated by reference in its entirety.

### FIELD

The field relates generally to the preparation of ingots of semiconductor or solar-grade material, more particularly, to methods and devices for loading and dispensing dopant during the production of ingots.

### BACKGROUND

Single crystal silicon, which is the starting material for most processes for the fabrication of semiconductor electronic devices and solar cells, is commonly prepared by the so-called Continuous Czochralski (“CCz”) or Czochralski (“Cz”) methods. In these methods, polysilicon in the form of solid feedstock material is charged to a crucible and melted, a seed crystal is brought into contact with the molten silicon or a melt, and a single crystal is grown by slow extraction.

Dopant may be added to the melt to achieve a desired resistivity in the silicon. Conventionally, the silicon melt is doped by feeding a dopant into the melt from a feed hopper located above the silicon melt.

The typical loading process of the feed hopper includes individually placing small pellets into a dispenser tube of the dopant dispenser or feed hopper by hand. In some applications, an operator may need to individually position a large number of pellets, e.g., 600 or more pellets, in the dispenser tube. As will be understood, this is a very tedious process. Additionally, handling the pellets may cause contamination, and thereby degrade the quality of the silicon product. In view of the above, it can be seen that a need exists for a simple, cost-effective approach to improve the efficiency associated with loading a dopant dispenser.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

A first aspect is a dopant funnel for loading dopant pellets into a dispenser tube of a dopant dispenser. The dopant funnel includes a cup for holding the dopant pellets, and a shaft. The cup has a restrictor to meter the number of dopant pellets and to orient the dopant pellets. The shaft is in alignment with the restrictor for delivering the dopant pellets from the cup to the dispenser tube.

Another aspect is a method for loading a dispenser tube of a dopant dispenser for use in a crystal pulling system with a dopant funnel having a cup connected through a restrictor with a shaft. The method includes loading the cup of the dopant funnel with randomly oriented dopant pellets, positioning the shaft in alignment with the dispenser tube, and causing a vibrating movement of the dopant funnel to induce movement of the dopant pellets with respect to the dopant funnel.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a front elevation of a dopant funnel in accordance with one embodiment;

FIG. 2 is a top view of the dopant funnel in accordance with FIG. 1;

FIG. 3 is a side view of the dopant funnel in accordance with FIGS. 1-2; and

FIG. 4 is a front perspective view of the dopant funnel in accordance with FIGS. 1-3, loading a plurality of dopant pellets into a dispenser tube of a dispenser.

Corresponding reference characters indicate corresponding parts throughout the several views of the drawings.

### DETAILED DESCRIPTION

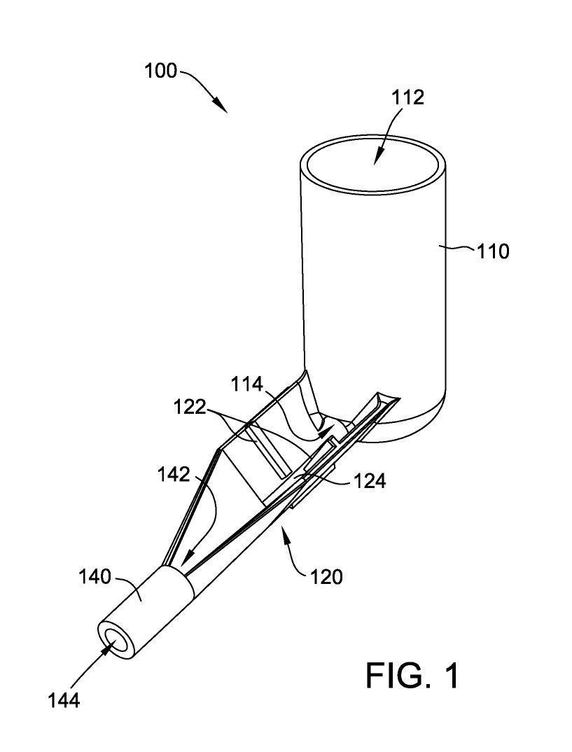

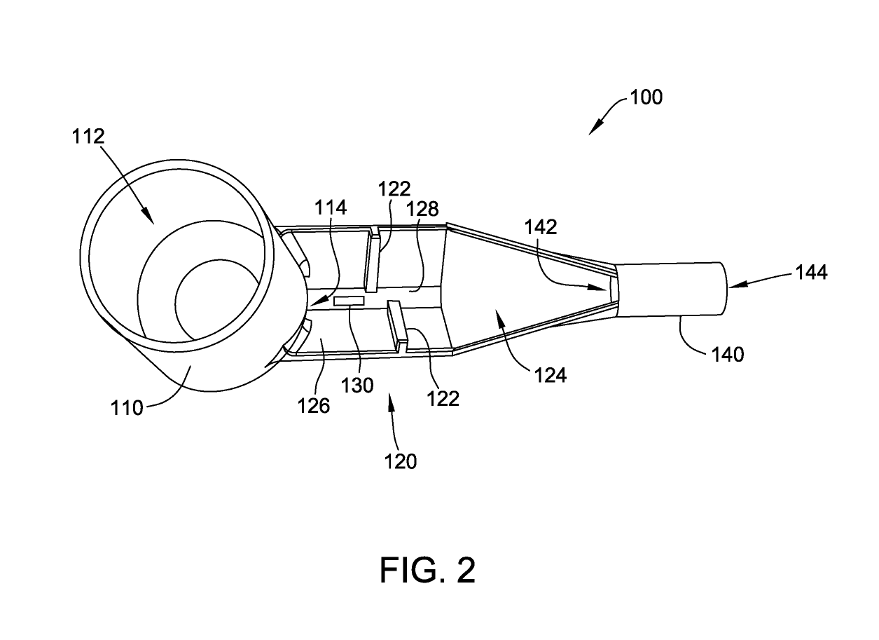

Referring to FIGS. 1 and 2, a dopant funnel for use in loading dopant is generally indicated at 100. The funnel 100 is configured for loading dopant pellets into a dispenser tube of a dopant dispenser of a single-crystal pulling system, though other applications of the funnel are contemplated. The dopant funnel 100 is suitably made of a high purity material, such as high purity quartz, to reduce or eliminate possible contamination of the dopant pellets.

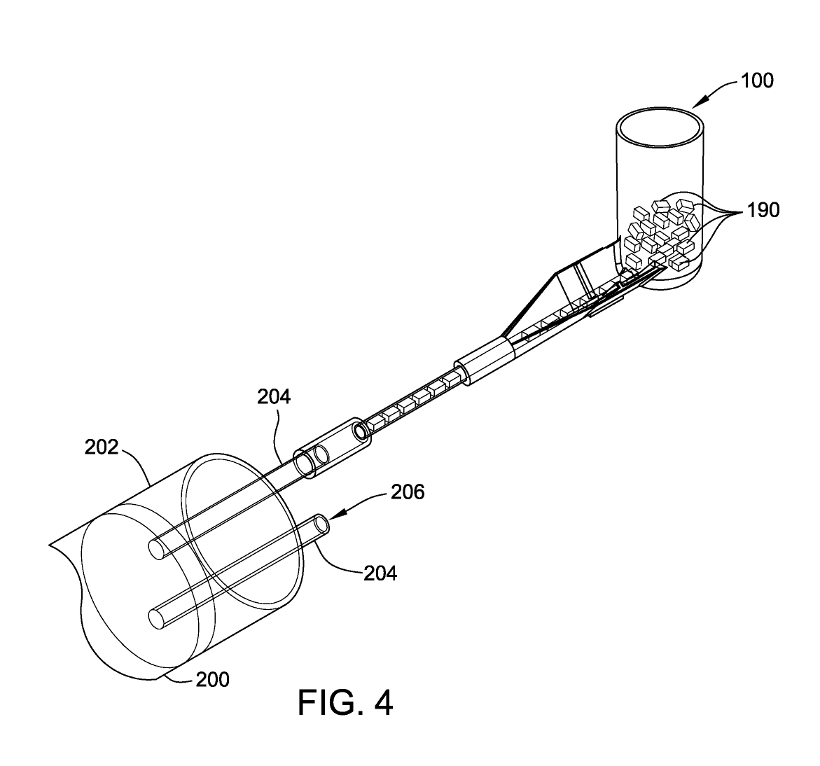

The dopant funnel 100 includes a cup 110 for holding a plurality of dopant pellets 190, as shown in FIG. 4. The cup 110 defines a cavity 112 connected with an opening in the form of a restrictor 114 to aid in alignment of the dopant pellets 190 as the dopant pellets pass from the cup through the restrictor. The restrictor 190 acts to meter the number of dopant pellets exiting the cup 110 during operation of the dopant funnel 100.

A shaft 120 is connected with the cup 110 around the restrictor 114 and extends outward therefrom. The shaft 120 has a straight semi-cylindrical body 126 having baffles 122 adjacent each side to aid in the alignment of the dopant pellets 190 with the shaft and prevent unaligned dopant pellets from passing thereby. The lowermost portion of the shaft 120 defines a trough 124 that has a length and a bottom 128 for supporting the dopant pellets as the dopant pellets move along the length of the trough.

The baffles 122 terminate at a distance that is equal to approximately one pellet diameter length from the bottom 128 of the trough 124. The baffles 122 are sized and shaped to allow aligned pellets 190 to pass by the baffles 122, and to prevent unaligned pellets 190 from passing thereby. The shape and size of the baffles 122, and their relative positions, are based on the dimensions of the pellets 190. The baffles 122 are spaced from each other along the longitudinal axis of the trough. In other embodiments, the shaft may include at least one baffle that is positioned opposite another baffle.

Dopant pellets of this embodiment have a standard or specific size and mass or weight, so that the exact amount of dopant being delivered to the crystal pulling system is known. These dopant pellets have a standard pellet diameter or width and standard pellet length. As a result, a constant wafer resistivity can be achieved by dispensing a predetermined number of pellets. During transport or loading the dopant pellets may become broken resulting in a broken dopant pellet that has a diameter or length that is less than the standard unbroken size.

The shaft 120 includes at least one slot 130 located along the bottom 128 of the trough 124 for removing or extracting broken pellets during the loading process. The slot 130 has a slot length that is less than the standard pellet length and a width that is substantially equivalent to the standard pellet diameter. As the pellets 190 move across the length of the shaft 120 and over the slots 130, broken pellets are unable to traverse the length of the slot and therefore are dropped downward through the slot 130.

With additional reference to FIG. 4, the construction described above enables the crystal pulling system 200 to be loaded with a dopant dispenser 202 having a known amount of dopant, which enables the dispenser to dispense a specific amount of dopant during the crystal forming process. Accordingly, the resistivity of the product can be determined by the quantity of loaded dopant in the dispenser tube 202.

The shaft 120 terminates in a delivery tube 140. The delivery tube 140 has a passage 142 terminating in an orifice 144 sized to accept/receive a portion of the dispenser tube 204 therein, and to align the pellets 190 within the trough 124 with a passageway 206 extending through the dispenser tube. The alignment of the delivery tube 140 with the dispenser tube 204 allows the dopant pellets 190 to pass unobstructed from the shaft 120 into the delivery tube.

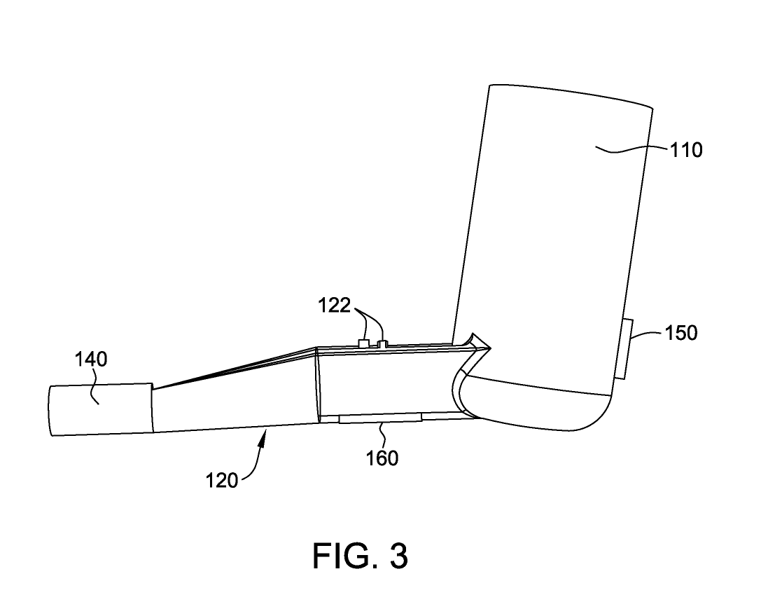

To facilitate the movement and subsequent alignment of the pellets 190 with the passageway 206, the funnel 100 includes a first vibrator 150 and a second vibrator 160, as shown in FIG. 3. The first vibrator 150 is attached to the cup 110 to induce an initial movement of the pellets 190 for alignment and passage through the restrictor 114. The second vibrator 160 is located along the shaft 120 to facilitate alignment and passage of the pellets 190 through the baffles 122 and along the length of the shaft. In other embodiments, more or less vibrators may be used in the same or other locations along the dopant funnel.

In some embodiments, a vibrator 150, 160 is located adjacent to one of the restrictor 114 and the baffle 122.

In operation, an operator loads the cup 110 with randomly oriented pellets 190. The dopant funnel 100 is aligned with the dispenser tube 204 and the delivery tube 140 is placed over the dispenser tube. The operator then activates the vibrators 150, 160, which causes a vibrating movement. The vibrating movement induces the pellets 190 to move and shift in location relative to the funnel 100. As the pellets 190 move and shift, some of the pellets are aligned with the restrictor 114 and move out of the cup 110 and down the shaft 120. As the pellets 190 are moved between the restrictor 114 and the baffles 122 any broken pellets fall out of the funnel 100 through the slots 130. Any unaligned pellets are then aligned as the pellets 190 pass by the baffles 122.

The time required to load the pellets may be decreased using the above method, e.g. from about 30 to 40 minutes to less than approximately 5 minutes.

Once the pellets 190 are aligned and any broken or chipped pellets are expelled, the pellets pass the length of the shaft 120 and through the delivery tube 140 and into the dispenser tube 202.

Use of the above embodiments reduces the contact and thereby the risk of contamination of the dopant. As described above, the operator need not touch the pellets. Because touching with potentially contaminated hands or gloves may contaminate the dopant, reducing the contact reduces the risk of contamination. Additionally, use of the dopant funnel significantly reduces the time required to load the dispenser tubes. This reduction in risk and improved efficiency not only increases the overall production of the crystal forming system, but also lowers overall operational costs.

When introducing elements of the present disclosure or the embodiments thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A dopant funnel for loading dopant pellets into a dispenser tube of a dopant dispenser, the dopant funnel comprising:
a cup for holding the dopant pellets, the cup having a restrictor to meter the number of dopant pellets exiting the cup;
a shaft in alignment with the restrictor for delivering the dopant pellets from the cup to the dispenser tube.

2. The dopant funnel of claim 1, further comprising a delivery tube connected with the shaft for aligning the shaft with the dispenser tube.

3. The dopant funnel of claim 2, wherein the delivery tube includes a passage terminating in an orifice sized to receive the dispenser tube therein.

4. The dopant funnel of claim 1, wherein the shaft includes a trough aligned with the passage through the delivery tube.

5. The dopant funnel of claim 4, wherein the trough includes a length and a bottom for supporting the dopant pellets as the dopant pellets move along the length of the trough, the bottom of the trough includes a slot to extract broken pellets as the dopant pellets move along the length of the trough.

6. The dopant funnel of claim 5, wherein the slot has a slot length that is less than one pellet length.

7. The dopant funnel of claim 5, wherein the slot has a slot width that is more than one pellet diameter to allow the broken pellets to be extracted through the slot.

8. The dopant funnel of claim 1, wherein the shaft includes a length, a bottom for supporting the dopant pellets as the dopant pellets move along the length of the shaft, and a baffle for aligning the dopant pellets as the dopant pellets move along the length of the shaft.

9. The dopant funnel of claim 8, wherein the baffle terminates at a distance from the bottom of the shaft equal to approximately one pellet diameter to prevent unaligned dopant pellets from moving past the baffle.

10. The dopant funnel of claim 1, wherein the shaft includes a plurality of baffles, wherein at least two of said baffles are disposed opposite one another.

11. The dopant funnel of claim 1, further comprising a vibrator for causing movement of the dopant pellets with respect to the dopant funnel.

12. The dopant funnel of claim 11, wherein a baffle is disposed along the shaft for alignment of the dopant pellets and the vibrator is located adjacent to one of the restrictor and the baffle.

13. A method for loading a dispenser tube of a dopant dispenser for use in a crystal pulling system with a dopant funnel having a cup connected through a restrictor with a shaft, the method comprising:
loading the cup of the dopant funnel with randomly oriented dopant pellets;
aligning the shaft with the dispenser tube; and
causing a vibrating movement of the dopant funnel to induce movement of the randomly oriented dopant pellets with respect to the dopant funnel.

14. The method of claim 13, wherein the vibrating movement is provided by a vibrator connected to the dopant funnel.

15. The method of claim 14, wherein causing a vibrating movement includes activating the vibrator.

16. The method of claim 13, wherein the shaft includes a length and a baffle for aligning the randomly oriented dopant pellets as the dopant pellets move along the length of the shaft.

17. The method of claim 16, wherein the shaft includes a vibrator located adjacent to the baffle.

18. The method of claim 13, wherein the vibrating movement align pellets with the restrictor to allow the pellets to move out of the cup.

19. The method of claim 13, wherein the shaft includes a slot for extracting broken pellets from the dopant funnel.

20. The method of claim 13, wherein the loading of the cup includes loading the cup with dopant pellets having a specific unbroken size, including a standard pellet width and standard pellet length.
